(19) United States
(12) Patent Application Publication
(10) Pub. No.: US 2026/0169107 A1
(43) Pub. Date: Jun. 18, 2026

(54) DUAL-RESONANT MAGNETIC RESONANCE TOMOGRAPHY LOCAL COIL WITH INTEGRATED PILOT TONE SIGNAL FREQUENCY CONVERTER

(71) Applicant: Siemens Healthineers AG, Forchheim (DE)

(72) Inventors: Jan Bollenbeck, Eggolsheim (DE); Peter Speier, Erlangen (DE)

(21) Appl. No.: 19/411,705

(22) Filed: Dec. 8, 2025

(30) Foreign Application Priority Data
Dec. 13, 2024 (DE) 10 2024 211 898.2

(51) Int. Cl. G01R 33/36

(52) U.S. Cl. CPC G01R 33/3621

(57) ABSTRACT

A local coil for a magnetic resonance tomography device is provided to acquire a magnetic resonance signal and a pilot tone signal and to pass them on to a receiver of the magnetic resonance tomography device for evaluation. The pilot tone signal lies in a first frequency range that is disjoint and has a frequency spacing from a second frequency range in which the magnetic resonance signal lies. The local coil has at least one frequency converter that is configured to convert the pilot tone signal and the magnetic resonance signal into a common frequency range.

The present patent document claims the benefit of German Patent Application No. 10 2024 211 898.2, filed Dec. 13, 2024, which is hereby incorporated by reference in its entirety.

### TECHNICAL FIELD

The disclosure relates to a local coil for receiving a pilot tone signal and to a magnetic resonance tomography device with a local coil. The magnetic resonance system has a receiver configured to simultaneously receive and evaluate a pilot tone signal and a magnetic resonance signal fed to the receiver by the local coil.

### BACKGROUND

Magnetic resonance tomography (MRT) devices are imaging apparatuses, which, for imaging an examination object, align nuclear spins of the examination object with a strong external magnetic field and, by way of an alternating magnetic field, excite them into precession about this alignment. The precession and/or the return of the spin from this excited state into a state with lower energy itself generates an alternating magnetic field as the response, which is received via antennae.

With the aid of magnetic gradient fields, a position encoding is impressed upon the signals, which subsequently enables an association of the received signal with a volume element. The received signal is then evaluated and a three-dimensional imaging representation of the examination object is provided.

The magnetic resonance signals are very weak. In order to achieve a sufficiently high signal-to-noise ratio, the signal is therefore to be acquired over a long period of time in one or in repeated measurements. The acquisition of the magnetic resonance signals is therefore slow as compared with unavoidable movements of the patient such as a heartbeat or breathing movements. The movements cause artifacts in the images that are generated.

However, one possibility for imaging the moving organs comes about if a short image acquisition is carried out repeatedly synchronized with the movement and averaging is applied across the acquired data.

A synchronization may take place using dedicated sensors such as, for example, a respiratory belt or ECG electrodes.

In order to avoid the use of these additional sensors, it is known from U.S. Patent Application Publication No. 2015/0320342 A1 to couple a continuous mono-frequency alternating magnetic field emerging from a small conductor loop, at least partially, through the body of the patient into the individual elements of a local magnetic resonance coil.

Since most biological tissue is almost completely transparent to magnetic fields, the magnetic field generated permeates the body of the patient almost unchanged. Most tissues are, however, (weakly) conductive and therefore the continuous alternating magnetic field induces eddy currents. These eddy currents in turn generate a magnetic field which is overlaid upon the excitation field, which leads to modulations in the magnetic field received in the receiving coil.

By way of the evaluation of this signal, a movement phase of the heart or the breathing may be deduced.

The cost for hardware is reduced if, for the acquisition of the movement, a signal is used which has a frequency close to the frequency of the magnetic resonance signal and may therefore be evaluated with the same receiver, e.g., simultaneously. For heart movements, in particular, the degree of the modulation is severely reduced with increasing frequency so that in magnetic resonance systems for low static magnetic field strengths B0, for example, of 0.5 T, a reliable recognition of the heartbeat in this way is barely still possible.

In certain examples, a local coil may undertake a frequency conversion of the pilot tone signal into a common frequency range with the magnetic resonance signal.

### SUMMARY AND DESCRIPTION

It is therefore an object of the present disclosure to improve the local coil. This object is achieved with a local coil as disclosed herein. The scope of the present disclosure is defined solely by the appended claims and is not affected to any degree by the statements within this summary. The present embodiments may obviate one or more of the drawbacks or limitations in the related art.

The local coil is provided for use with a magnetic resonance tomography device in order to record magnetic resonance signals of a patient or an object in a static magnetic field B0 of the magnetic resonance tomography device. The frequency of the magnetic resonance signal is defined by the magnetic field strength B0 and a magnetic moment of the nuclear spin that is to be acquired and is known as the Larmor frequency. The expression local coil includes the elements needed for operating the coil, such as cables, plugs, and connections, and/or adaptors in the connection line to the magnetic resonance tomography device.

The local coil is configured, in particular, to acquire a magnetic resonance signal and a pilot tone signal and to pass them on to a receiver of the magnetic resonance tomography device for evaluation. As used herein, the term acquiring may refer to the conversion of the magnetic and/or electromagnetic radio-frequency alternating field of the nuclear spin and the pilot tone signal by an antenna and/or induction loop into an electrical signal. As used herein, pilot tone may refer to a magnetic and/or electromagnetic radio-frequency signal emitted by a pilot tone emitter that may be integrated into the local coil, the pilot tone interacting with the patient so that, by way of the patient's movements such as the breathing movement or heartbeat, a modulation of the pilot tone to a pilot tone signal takes place. The recording may also include further signal processing acts such as amplification or filtration.

The pilot tone and thus the pilot tone signal acquired by the antenna and/or induction loop lie within a first frequency range, wherein frequency range denotes a spectral range that includes the frequency of the pilot tone and at least side bands caused by the modulation. The first frequency range may include a bandwidth of more than 10 Hz, 100 Hz, 1 kHz, 10 kHz, or even 100 kHz.

The magnetic resonance signal acquired by the antenna and/or induction loop lies within a second frequency range that includes the already defined Larmor frequency of the magnetic resonance tomography device for which the local coil is configured. The bandwidth of the second frequency range may be specified by the bandwidth of the magnetic resonance signals that itself depends upon the slice thicknesses that are to be acquired and the magnetic field strengths of gradients for spatial encoding. A bandwidth of the second frequency range may include more than 100 kHz, 50 kHz, 1 MHz, or 5 MHz. According to the disclosure, the term magnetic resonance signal is also used to refer to the processed magnetic resonance signal and also possibly to the frequency-converted magnetic resonance signal.

In this regard, the first frequency range and the second frequency range are disjoint. A signal that is in the first frequency range is not part of the second frequency range and vice versa. In particular, it is also conceivable that a frequency in the first frequency range is a whole number multiple of a frequency in the second frequency range. The frequency ranges have a frequency spacing that is substantial in comparison with, for example, a central frequency or a bandwidth of one of the frequency ranges, for example, greater than a whole number multiple thereof with n>1.

The local coil has a frequency converter. A frequency converter is an apparatus that converts a signal from one frequency into another. The frequency converter may be realized with a non-linear element that converts a first signal with a first frequency by mixing, for example, multiplication or another non-linear operation, with a second signal to one or more other frequencies.

The frequency converter converts the acquired pilot tone signal into a common frequency range with the magnetic resonance signal.

For this purpose, a first frequency converter may convert the pilot tone signal into the frequency range in which the magnetic resonance signal emitted by the nuclear spin is found, that is, the common frequency range of the second frequency range.

Alternatively, the first frequency converter may convert the pilot tone signal into a common frequency range that is disjoint from the first frequency range and the second frequency range. The magnetic resonance signal acquired by the antenna is converted, by a second frequency converter or by the first frequency converter, into the common frequency range. This may be an intermediate frequency that prevents back-coupling to the input signal, reduces the damping on transfer to the magnetic resonance tomography device, and/or serves for a frequency multiplexing.

In other words, the pilot tone signal is converted from the first frequency range into a common frequency range with the magnetic resonance signal so that the converted pilot tone signal may subsequently be processed and evaluated by a receiver for the magnetic resonance signal.

In certain examples, the frequency conversion takes place such that the magnetic resonance signal and the converted pilot tone signal in the second frequency range do not overlap but rather are adjacent to one another. This may be achieved, for example, by way of a suitable selection of the frequency of a mixing and/or oscillator signal.

In an advantageous manner, the frequency converter of the local coil enables the pilot tone signal to have a higher frequency than the magnetic resonance signal but nevertheless to be processed by a receiver for the magnetic resonance signal. In magnetic resonance tomography devices, in particular, having a low static magnetic field, a pilot tone solution with a high level of movement sensitivity may thus be provided in an inexpensive manner.

The local coil has an amplifier unit for amplifying the magnetic resonance signal. This denotes, in particular, a low-noise preamplifier that is arranged, for amplifying the magnetic resonance signal, directly behind the antenna coil and is also referred to as an LNA (low noise amplifier).

The frequency converter is formed by the amplifier unit. This may be understood to mean that the non-linear operation is carried out by an active element of the amplifier unit and that the amplification of the magnetic resonance signal is carried out by the LNA. In certain examples, the amplifier element is a transistor, for example, a bipolar transistor or a field effect transistor.

In advantageous manner, the use of the LNA as a mixer reduces the complexity and thus, in particular, also the current demand and the heat losses in the local coil.

In an embodiment of the local coil, the amplifier unit is a transistor. The input signal, in particular, the pilot tone signal is converted by the frequency converter into another frequency range by being mixed with a mixed signal and/or an oscillator signal. For this purpose, the mixed signal is fed to the frequency mixer. If the mixer is implemented, as here, by way of a transistor as the amplifier element, one possibility is to make use of the coupling by way of the parasitic capacitances between the transistor control input (for example base) and the transistor output (for example collector) for coupling in the mixed signal. Since the mixed signal is available at a greater amplitude, even the low level of coupling by way of the parasitic capacitance is sufficient. The use of other parasitic couplings from output terminals to the input is also conceivable, for example, from the emitter or the drain and/or the source in the case of an FET transistor.

In a possible embodiment of the local coil, the mixed signal is fed via a filter into the output terminal. Filters may be understood here, in particular, as elements that have a frequency-dependent transfer function, for example, high-pass, low-pass, or band-pass filters. In an advantageous manner, dependent upon the frequency position of the mixed signal, the pilot tone signal and the magnetic resonance signal, these signals are decoupled from one another.

In a conceivable embodiment of the local coil, the local coil has a plurality of antenna coils. The amplifier unit has at least two cascaded stages. Cascaded stages may be understood here to be amplifier elements that are connected directly after one another, which may be connected only via passive components and arranged situated spatially close, e.g., in the local coil. In particular, in a first stage, a first amplifier element is associated with each antenna coil, for example, in order to decouple the antenna elements. In a second stage, at least the signals from two first stages are brought together and amplified in an amplifier element of the second amplifier stage. The frequency converter is realized by way of an amplifier element of the second stage. As stated above, the amplifier element with the mixer function differs from a pure mixer by its amplification of the magnetic resonance signal.

In an advantageous manner, in a cascaded amplifier unit, the frequency conversion may be included in the second stage and so the number of components may be reduced, wherein the antenna coils remain decoupled from the frequency mixing and the mixed signal.

In one possible embodiment of the local coil, a mixing amplification of the amplifier unit is set low such that a noise component caused by the mixing in a frequency range of the magnetic resonance signal is negligible. The mixing amplification is defined here as the ratio of the amplitudes of the signals to be mixed at the input of the mixer, here the pilot tone, to an amplitude of the mixing product provided at the output of the mixer, here the frequency-converted pilot tone signal. The mixing amplification is therein firstly dependent upon the classic amplification of the mixer itself, that is, for example, with a transistor as the mixer, upon its intrinsic current gain and the circuit configuration. Furthermore, the amplitude of the mixing product depends upon an amplitude of the oscillator signal with which the input signal is mixed in the mixer. The mixing amplification may thus be influenced, independently of the amplification of the magnetic resonance signal, by raising the level of the oscillator signal in that, for example, the magnetic resonance tomography device raises its level.

The noise component may be regarded as negligible if an additional noise signal is lower by 12 dB or 20 dB due to the mixing than the noise contribution of the MR signal path. The additional noise component is caused, for example, by thermal noise in a frequency range that is converted by the mixing to the frequency of the magnetic resonance signal. The mixing amplification may advantageously be set above the level of the LO signal. This may also take place in a sequence-dependent manner, for example, dependent upon an expected amplitude of the magnetic resonance signal. Since the mixing process is a second order intermodulation, the level of the mixing product is proportional to the LO signal level.

Advantageously, by way of the amplifier unit, a signal mixing may be provided without any noticeable worsening of the imaging.

A system has a local coil as described herein and a magnetic resonance tomography device. The magnetic resonance tomography device provides a signal that is coupled into the patient via an induction loop and interacts with him. The response signal formed by induced eddy currents becomes overlaid upon the exciting field to a total signal which is acquired and evaluated as a pilot tone signal, (e.g., by an antenna coil), together with the magnetic resonance signals. The magnetic resonance tomography device is configured to provide the pilot tone transmission signal fed to the coupling-in induction loop with such a high level that the acquired pilot tone signal has a sufficient SNR for the evaluation of the patient movement. In particular, by this means, the previously described low mixing amplification of the amplifier unit may be compensated for. In certain examples, the magnetic resonance tomography device may provide an automatic and/or dynamic compensation function, which may raise a level of the oscillator signal and/or the mixed signal if the mixed down pilot tone signal provided for evaluation has an amplitude that is too low or an SNR that is too poor.

In an advantageous manner, the system may thus provide a consistent quality of the pilot tone signal and of the movement detection thereby provided.

The above-described properties, features, and advantages of this disclosure and the manner in which they are achieved are made more clearly and distinctly intelligible with the following description of the exemplary embodiments that are set out in greater detail making reference to the drawings.

### BRIEF DESCRIPTION OF THE DRAWINGS

FIG. 1 shows a schematic representation of an example of a magnetic resonance system with a local coil.

FIG. 2 shows a schematic representation of an exemplary embodiment of a local coil.

FIG. 3 shows a schematic representation of an exemplary embodiment of a local coil.

FIG. 4 shows a schematic representation of an exemplary embodiment of a local coil in conjunction with a magnetic resonance tomography device.

### DETAILED DESCRIPTION

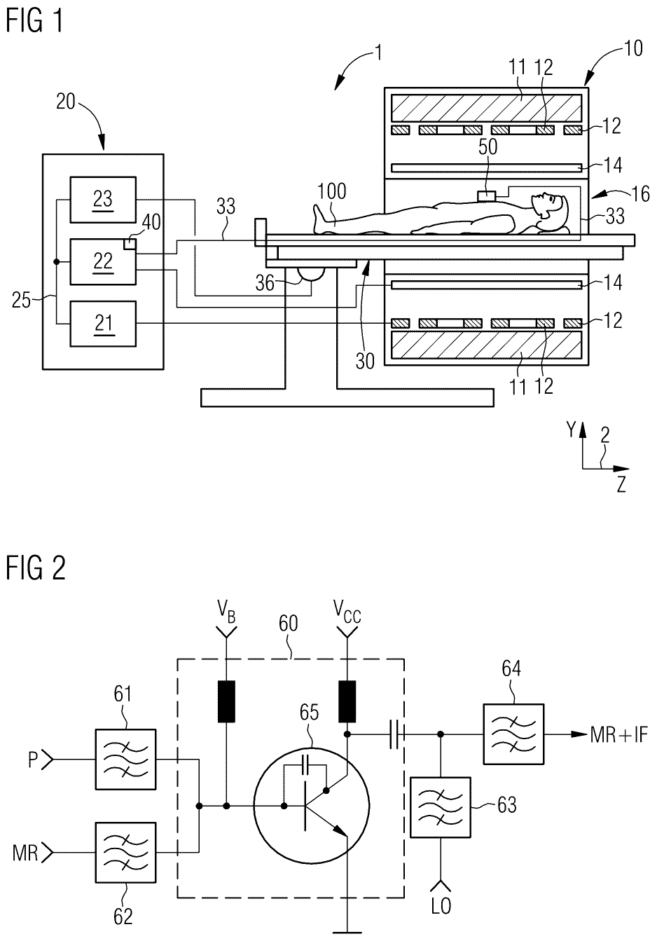

FIG. 1 shows a schematic representation of an embodiment of a magnetic resonance system 1 with a local coil 50.

The magnet unit 10 has a field magnet 11 that generates a static magnetic field B0 for aligning the nuclear spins of samples and/or of the patient 100 in a scanning region. The scanning region is characterized by an extremely homogenous static magnetic field B0, wherein the homogeneity relates, in particular, to the magnetic field strength and/or the orientation and the quantity. The scanning region is almost spherical and is arranged in a patient tunnel 16 which extends in a longitudinal direction 2 through the magnet unit 10. A patient support 30 is movable in the patient tunnel 16 by the displacement unit 36. In certain examples, the field magnet 11 is a superconducting magnet which may provide magnetic fields with a magnetic flux density of up to 3 T and, in the newest devices, even higher. For lower field strengths, however, permanent magnets or electromagnets with normally-conducting coils may also be used.

The magnet unit 10 further includes gradient coils 12 that are designed, for spatial differentiation of the acquired imaging regions in the examination volume, to overlay variable magnetic fields onto the magnetic field B0 in three spatial directions. The gradient coils 12 may be coils made of normally conducting wires which may generate mutually orthogonal fields in the examination volume.

The magnet unit 10 also has a body coil 14 configured to couple a radio-frequency signal fed via a signal line into the examination volume and to receive resonance signals emitted from the patient 100 and to pass them on via a signal line.

A control unit 20 supplies the magnet unit 10 with the different signals for the gradient coils 12 and the body coil 14 and evaluates the received signals.

Thus, the control unit 20 includes a gradient controller 21 configured to supply the gradient coils 12 via feed lines with variable currents that provide the desired gradient fields in the examination volume in a temporally coordinated manner.

Furthermore, the control unit 20 has a radio-frequency unit 22 configured to generate a radio-frequency magnetic field pulse with a pre-determined temporal pattern, amplitude, and spectral power distribution for the excitation of a magnetic resonance of the nuclear spins in the patient 100. Therein, pulse power levels in the kilowatt range may be achieved. The excitation pulses may be emitted into the patient 100 via the body coil 14 or via a local transmitting antenna.

The radio-frequency unit 22 also has a receiver 40 for receiving and/or for preparing a magnetic resonance signal from the patient 100 that is acquired by the local coil 50 and is transferred via a signal connection to the receiver 40. The receiver 40 is also configured to receive and evaluate a pilot tone.

In one embodiment, the radio-frequency unit 22 also has a pilot tone emitter 70 which transfers a pilot tone to a pilot tone transmitting antenna and/or coupling loop, possibly also arranged in the local coil 50 for coupling out via a signal connection. Also conceivable, however, is a separate pilot tone emitter 70 that acts independently of the magnetic resonance system 1.

A control system 23 communicates via a signal bus 25 with the gradient controller 21 and the radio-frequency unit 22.

Arranged on the patient 100 is a local coil 50 connected via a connection line 33 to the radio-frequency unit 22 and its receiver.

In certain examples, the local coil 50 further has a pilot tone transmitting antenna and/or coupling loop with which a pilot tone may be emitted and/or induced into the body of the patient 100. In certain examples, the pilot tone is generated by the coupling loop in the form of an alternating magnetic field which at least partially penetrates the body of the patient 100 and is coupled into the antenna coils 51 of the magnetic resonance tomography device 1.

FIG. 2 shows a schematic representation of an exemplary embodiment of an amplifier unit 60 of a local coil 50.

The amplifier unit 60 has a transistor 65 as the amplifier element. The transistor has a parasitic capacitance between the base and the collector, which is indicated by the capacitor within the circuit symbol. For an exemplary transistor BFR182W, 0.34 pF may exist. A pilot tone signal and a magnetic resonance signal are fed from receiving loops, such as, for example, the antenna coils 51, to the base of the transistor 65. The pilot tone signal P and the magnetic resonance signal MR may be filtered in advance via resonant elements such as, for example, the first filter 61 and the second filter 62. The connection, as shown, of the first filter 61 and the second filter 62 forms a so-called diplex filter with which the two signals of different central frequencies may be decoupled from one another and combined with proper impedance matching.

In an exemplary magnetic resonance tomography device 1 with a static magnetic field B0 of 0.55 T, there results a central frequency of the magnetic resonance signal of 23.6 MHz. The pilot tone has a frequency of 112.5 MHz. A mixed signal LO is fed in via the filter 63 and the collector, making use of the parasitic collector-base coupling capacitance. In order to convert the pilot tone into the frequency range of the magnetic resonance signal, the frequency of the mixed signal in the example is 90 MHz so that the difference between the frequencies of the pilot tone and the mixed signal is 22.5 MHz.

Due to the low spectral spacing between the MR signal (MR) and the frequency-converted pilot tone signal (IF), both signals may be acquired and further processed by the receiver simultaneously. The operating point of the transistor 65 and thus the non-linearity of the characteristic may be influenced via the base voltage and/or the bias voltage. Furthermore, the amplitude of the mixed signal may also be used to vary the amplitude of the converted-down pilot tone signal, which is filtered together with the magnetic resonance signal at the output by a fourth filter 64. The filter 64 is configured such that both the MR signal and also the IF signal may pass substantially undamped, whereas disruptive spectral components, in particular, higher-order signal harmonics and also the LO signal are suppressed.

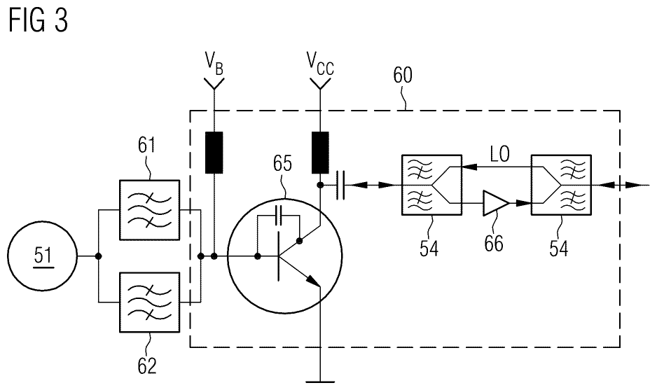

In FIG. 3, a variant of the amplifier unit 60 is shown, which, in a two-stage variant, may provide a higher amplification and/or better energy efficiency.

The signal induced in the antenna coils 51 may be filtered by the filters 61 and 62. However, it is also conceivable that the antenna coils 51 themselves are double-resonant at the frequency of the pilot tone and of the magnetic resonance signal. The first filter 61 and the second filter 62 may also perform the function of an adapting member for adapting the impedance of the antenna coil to the input of the amplifier unit 60.

The first amplifier stage is formed by the transistor 65 as is already disclosed in the description relating to FIG. 2. What differs, however, is the manner in which the mixed signal is fed to the transistor 65. Via a common signal route, the local coil 50 is fed both the mixed signal and also the frequency-converted pilot tone signal and the magnetic resonance signal is transferred to the magnetic resonance tomography device 1. In order to be able to amplify the magnetic resonance signal in the second amplifier stage 66, the mixed signal and the magnetic resonance signal are separated before the second amplifier stage via a diplexer 54 and then fed together again. Since the mixed signal may have a higher frequency than the magnetic resonance signal, the diplexers 54 may be realized by way of, respectively, a high-pass filter and a low-pass filter.

In an advantageous manner, the second amplifier 66 may be configured narrow-band because the second amplifier only amplifies the common narrow frequency range of the magnetic resonance signal and the converted pilot tone signal. Thus, the same amplification may be achieved with a lower energy expenditure as compared with a single-stage, broad-band amplifier stage with the same amplification.

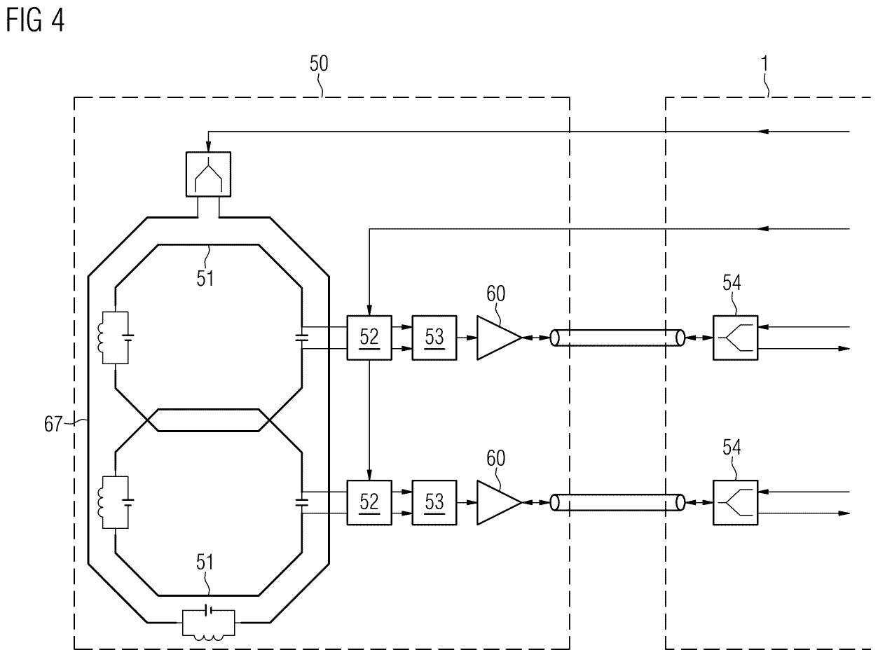

FIG. 4 shows a further possible embodiment of a local coil 50 with a magnetic resonance tomography device 1. The pilot tone is fed by a radio-frequency unit 22 of the magnetic resonance tomography device 1 via a signal line of an induction loop 67 and is coupled as a radio-frequency alternating magnetic field into a patient 100.

The alternating magnetic field is accepted by the antenna loops 51 that are tuned to be double-resonant at the frequencies of the pilot tone and the magnetic resonance signal. The antenna loops 51 are further coupled to a tuning adjustment apparatus 52 that makes the antenna loops non-resonant at the frequency of the excitation pulse during the emission of the excitation pulse. The signal of the antenna coils 51 is passed on via an adaptation circuit 53 to an amplifier unit 60, as described above in relation to FIG. 2.

The local coil 50 is in signal-conducting connection with the magnetic resonance tomography device 1 via a signal line. The magnetic resonance signal and the pilot tone signal are fed by the local coil 50 in a common frequency range so that a frequency diplexer 54 may multiplex the mixed signal fed to the local coil 50 and the pilot tone signal and the magnetic resonance signal coming from the local coil 50 on the signal connection.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A local coil for a magnetic resonance tomography device, the local coil comprising:
an amplifier unit; and
at least one frequency converter,
wherein the local coil is configured to acquire a magnetic resonance signal and a pilot tone signal,
wherein the local coil is configured to pass the magnetic resonance signal and the pilot tone signal on to a receiver of the magnetic resonance tomography device for evaluation,
wherein the pilot tone signal lies in a first frequency range,
wherein the magnetic resonance signal lies in a second frequency range,
wherein the first frequency range is disjoint from the second frequency range,
wherein the at least one frequency converter is configured to convert the pilot tone signal and the magnetic resonance signal into a common frequency range,
wherein the amplifier unit is configured to amplify the magnetic resonance signal, and
wherein the at least one frequency converter is formed by the amplifier unit.

2. The local coil of claim 1, wherein the amplifier unit comprises a transistor.

3. The local coil of claim 2, wherein a combined signal from the magnetic resonance signal and the pilot tone signal is configured to be coupled into an input terminal of the transistor.

4. The local coil of claim 3, wherein a mixed signal to the frequency converter is configured to be coupled in via an output terminal of the transistor.

5. The local coil of claim 4, wherein an output signal from an amplified magnetic resonance signal and a frequency-converted pilot tone signal is configured to be coupled out from the output terminal of the transistor.

6. The local coil of claim 4, wherein the mixed signal is configured to be coupled into the output terminal.

7. The local coil of claim 1, wherein a mixing amplification of the amplifier unit is set such that a noise component caused by the mixing in a frequency range of the magnetic resonance signal is negligible.

8. The local coil of claim 1, wherein the first frequency range is a whole number multiple of the second frequency range, and
wherein the whole number multiple is greater than 1.

9. The local coil of claim 8, wherein the first frequency range has a bandwidth of more than 10 Hz.

10. The local coil of claim 1, wherein the first frequency range has a bandwidth of more than 10 Hz.

11. A system comprising:
a local coil; and
a magnetic resonance tomography device,
wherein the local coil comprises:
an amplifier unit; and
at least one frequency converter,
wherein the local coil is configured to acquire a magnetic resonance signal and a pilot tone signal,
wherein the local coil is configured to pass the magnetic resonance signal and the pilot tone signal on to a receiver of the magnetic resonance tomography device for evaluation,
wherein the pilot tone signal lies in a first frequency range,
wherein the magnetic resonance signal lies in a second frequency range,
wherein the first frequency range is disjoint from the second frequency range,
wherein the at least one frequency converter is configured to convert the pilot tone signal and the magnetic resonance signal into a common frequency range,
wherein the amplifier unit is configured to amplify the magnetic resonance signal, and
wherein the at least one frequency converter is formed by the amplifier unit, and
wherein the magnetic resonance tomography device is configured to compensate for a worsened signal-to-noise ratio of the pilot tone signal by raising a mixed signal and/or an emitted pilot tone signal.
